(19) United States
(12) Patent Application Publication
(10) Pub. No.: US 2026/0299030 A1
(43) Pub. Date: Oct. 1, 2026

(54) PEIS FAULT PATTERN GENERATION METHOD AND APPARATUS FOR ELECTRIC VEHICLE BATTERY SAFETY DIAGNOSIS

(71) Applicants: HYUNDAI MOTOR COMPANY, Seoul (KR); KIA CORPORATION, Seoul (KR); The Industry & Academic Cooperation in Chungnam National University (IAC), Daejeon (KR)

(72) Inventors: Cheol Beom Lim, Hwaseong-si (KR); Jong Hoon Kim, Daejeon (KR)

(73) Assignees: HYUNDAI MOTOR COMPANY, Seoul (KR); KIA CORPORATION, Seoul (KR); The Industry & Academic Cooperation in Chungnam National University (IAC), Daejeon (KR)

(21) Appl. No.: 19/322,021

(22) Filed: Sep. 8, 2025

(30) Foreign Application Priority Data
Mar. 31, 2025 (KR) 10-2025-0041736

(51) Int. Cl. G01R 31/367; B60L 58/12; B60L 58/16; G01R 31/3842; G01R 31/389; G01R 31/392

(52) U.S. Cl. CPC G01R 31/367; B60L 58/12; B60L 58/16; G01R 31/3842; G01R 31/389; G01R 31/392

(57) ABSTRACT

A method and an apparatus generate a PEIS fault pattern which is used for electric vehicle battery pack safety diagnosis. The fault pattern generating method for electric vehicle battery safety diagnosis includes generating a pre-learning model based on a driving profile corresponding to a pre-owned battery cell, generating a new learning model for transfer learning based on the pre-learning model, and generating a fault passive electrochemical impedance spectroscopy (PEIS) pattern corresponding to a target battery cell by inputting current data corresponding to the target battery cell into the new learning model. The pre-owned battery cell includes an existing battery cell in a normal state, an existing battery cell in a faulty state, and the target battery cell in a normal state.

### CROSS-REFERENCE TO RELATED APPLICATION

This application claims the benefit of and priority to Korean Patent Application No. 10-2025-0041736, filed in the Korean Intellectual Property Office on Mar. 31, 2025, the entire disclosure of which is incorporated herein by reference.

### TECHNICAL FIELD

The present disclosure relates to an electric vehicle battery diagnosis technology.

### BACKGROUND

The safety of electric vehicle battery packs is one of the main issues for electric vehicles. Battery packs may have serious issues that affect the safe operation of electric vehicles, such as fire or explosion.

Accordingly, a battery pack safety diagnosis technology is very important for ensuring electric vehicle performance and driver safety.

Conventional direct current (DC)-based battery pack safety diagnosis algorithms diagnose safety based on mathematical models such that a battery management system (BMS) estimates the state of a battery. However, conventional DC-based battery pack safety diagnosis algorithms do not reflect and analyze the electrochemical mechanism of an actual battery in an on-board environment and thus does not accurately diagnose safety issues, which limits the reliability of the diagnostic results.

Each of cells within a battery pack module is composed of several components such as electrodes, electrolytes, and separators, making it difficult to accurately identify the status of the battery's internal electrochemical structure by using a simple sensor. In particular, sensors that measure the voltage, current, or temperature of a battery includes a specific level of error, which causes a decrease in the accuracy of the battery pack safety diagnosis results.

Moreover, battery safety issues are caused by various electrochemical causes such as an anode, a cathode, and a separator. However, in conventional DC-based battery pack safety diagnosis methods, there are limitations in securing reliability due to threshold-based diagnosis and the amount of change at corresponding time points such as sudden voltage drops.

### SUMMARY

The present disclosure provides a technical solution addressing the aforementioned problems occurring in the prior art while preserving advantages offered by those conventional methods.

To overcome the limitations of conventional DC-based battery pack safety diagnosis algorithms, an electrochemical impedance spectroscopy (EIS) diagnosis technique may be used to diagnose safety based on the electrochemical deterioration characteristics of the battery. However, the EIS diagnosis technique not only requires separate equipment for generating and measuring EIS signals but also includes limitations in applying it to actual Electric Vehicles (EVs) due to hardware specification limitations.

The EIS for electrochemically measuring of a battery is time-consuming because it requires data collection in several frequency bands, and in situations where real-time monitoring is required, the time consumption of EIS may cause significant issues. In other words, EIS-based battery pack safety diagnosis is limited in real-time monitoring.

To perform safety diagnosis based on the electrochemical characteristics of a battery, pattern information about the electrochemical characteristics of actual safety-retaining cells is required.

However, conventional EIS-based battery pack safety diagnosis methods are implemented to perform only a simple threshold-based Pass/Fail diagnosis because it is difficult to obtain electrochemical characteristic information (i.e., an EIS pattern for each fault type) for each battery fault type due to limitations in testing cells with safety issues.

Because cells constituting a battery pack include different internal chemical behaviors, there is a limitation in reproducing safety issues for testing and gathering data purposes. When different safety issues occur arbitrarily, it may not be possible to measure the voltage of a cell due to actual failure, or there is a possibility that an actual failure situation does not occur even when a fault condition (e.g., overcharge, over discharge, and short circuit) is applied.

Accordingly, the present disclosure provides a reliable and precise real-time battery pack safety diagnosis as a technical solution that overcomes limitations of conventional DC-based battery pack and EIS-based battery pack safety diagnosis methods.

Specifically, the present disclosure provides a technical solution that generates a Passive Electrochemical Impedance Spectroscopy (PEIS) fault pattern for a target battery cell by generating a new learning model for transfer learning based on a pre-learning model based on pre-owned battery information to diagnose the safety of electric vehicle battery packs.

An aspect of the present disclosure provides a method and an apparatus for generating a PEIS fault pattern that is used for electric vehicle battery pack safety diagnosis.

An aspect of the present disclosure provides an electric vehicle battery pack safety diagnosis technology that secures high-precision battery pack safety diagnosis performance by generating a PEIS fault pattern configured to simulate the electrochemical characteristics of a battery through signal processing of BMS input voltage and current raw signals.

An aspect of the present disclosure provides a method and an apparatus for generating a PEIS fault pattern configured to diagnose the high-precision safety of a battery by simulating a voltage behavior for each battery fault type, which is difficult to be obtained, by applying pre-owned faulty battery data-based model parameter estimation and transfer learning methods.

An aspect of the present disclosure provides a high-precision battery safety diagnosis technology that not only saves time and costs but also overcomes limitations in conventional battery safety verification, by simulating the voltage behavior suitable for the desired shape and type of a target battery by using the pre-owned battery with an unstable internal electrochemical state.

The technical problems to be solved by the present disclosure are not limited to the aforementioned problems. Any other technical problems not mentioned herein should be clearly understood from the following description by those of ordinary skill in the art to which the present disclosure pertains.

According to an aspect of the present disclosure, a fault pattern generating method for electric vehicle battery safety diagnosis includes generating a pre-learning model based on a driving profile corresponding to a pre-owned battery cell. The method further includes generating a new learning model for transfer learning based on the pre-learning model. The method further includes generating a fault passive electrochemical impedance spectroscopy (PEIS) pattern corresponding to a target battery cell by inputting current data corresponding to the target battery cell into the new learning model. The pre-owned battery cell includes an existing battery cell in a normal state, an existing battery cell in a faulty state, and the target battery cell in a normal state.

In an embodiment, generating the pre-learning model may include applying the driving profile to recursive least square (RLS) logic, extracting a model parameter for the respective pre-owned battery cell, and generating the pre-learning model by performing relationship learning on the extracted model parameter for the respective pre-owned battery cell.

In an embodiment, the pre-learning model may include a first pre-learning model generated by training parameter change logic based on occurrence of a fault between the existing battery cell in the normal state and the existing battery cell in the faulty state. The pre-learning model may further include a second pre-learning model generated by training parameter change logic based on a shape change between the existing battery cell in the normal state and the target battery cell in the normal state.

In an embodiment, a weight derived through relationship learning between the first pre-learning model and the second pre-learning model may be applied to the new learning model.

In an embodiment, the model parameter may include Rᵢ, R_{diff}, and C_{diff}. Rᵢ is resistance occurring when a lithium ion being removed from an electrode in an electrical equivalent circuit model for simulating a corresponding battery cell voltage. R_{diff} is resistance occurring based on the lithium ion moving inside electrolyte. C_{diff} is a charge amount of an electric double layer formed by oxidation-reduction reaction.

In an embodiment, the model parameter may be extracted for each battery state-of-charge (SOC).

In an embodiment, generating the fault PEIS pattern corresponding to the target battery cell may include extracting a fault model parameter corresponding to the target battery cell, constructing an electrical equivalent circuit model based on the extracted fault model parameter, estimating a fault terminal voltage of the target battery cell based on the electrical equivalent circuit model, and generating the fault PEIS pattern based on AC impedance data extracted through signal processing based on the fault terminal voltage.

In an embodiment, the fault terminal voltage may be estimated based on an open circuit voltage based on a battery charge state of the target battery cell and the extracted fault model parameter.

In an embodiment, the signal processing may include at least one of Discrete Wavelet Transform (DWT) or Short-Term Fourier Transform (STFT).

In an embodiment, safety diagnosis for the target battery cell may be performed by comparing a PEIS pattern with the fault PEIS pattern. The PEIS is generated based on a Battery Management System (BMS) voltage and current signal corresponding to the target battery cell.

According to an aspect of the present disclosure, a computing device that generates a fault pattern for diagnosing safety of an electric vehicle battery may include a memory configured to store computer-executable instructions. The computing device further includes a processor coupled with the memory. The processor is configured to execute the computer-executable instructions to generate a pre-learning model based on a driving profile corresponding to a pre-owned battery cell, generate a new learning model for transfer learning based on the pre-learning model, and generate a fault PEIS pattern corresponding to a target battery cell by inputting current data corresponding to the target battery cell into the new learning model. The pre-owned battery cell includes an existing battery cell in a normal state, an existing battery cell in a faulty state, and the target battery cell in a normal state.

In an embodiment, the processor may be further configured to extract a model parameter for the respective pre-owned battery cell by applying the driving profile to RLS logic. The processor may be further configured to generate the pre-learning model by performing relationship learning on the extracted model parameter for the respective pre-owned battery cell.

In an embodiment, the pre-learning model may include a first pre-learning model generated by training parameter change logic according to occurrence of a fault between the existing battery cell in the normal state and the existing battery cell in the faulty state. The first pre-learning model may include a second pre-learning model generated by training parameter change logic based on a shape change between the existing battery cell in the normal state and the target battery cell in the normal state.

In an embodiment, the processor may be further configured to apply a weight derived through relationship learning between the first pre-learning model and the second pre-learning model to the new learning model.

In an embodiment, the model parameter may include Rᵢ, R_{diff}, and C_{diff}. Rᵢ is resistance occurring based on a lithium ion being removed from an electrode in an electrical equivalent circuit model for simulating a corresponding battery cell voltage. R_{diff} is resistance occurring based on the lithium ion moving inside electrolyte. C_{diff} is a charge amount of an electric double layer formed by oxidation-reduction reaction.

In an embodiment, the model parameter may be extracted for each battery SOC.

In an embodiment, the processor may be further configured to construct an electrical equivalent circuit model by extracting a fault model parameter corresponding to the target battery cell, may estimate a fault terminal voltage of the target battery cell based on the electrical equivalent circuit model, and may generate the fault PEIS pattern based on AC impedance data extracted through signal processing based on the estimated fault terminal voltage.

In an embodiment, the processor may be further configured to estimate the fault terminal voltage based on an open circuit voltage according to a battery charge state of the target battery cell, and the extracted fault model parameter.

In an embodiment, the signal processing may include at least one of DWT or STFT.

In an embodiment, the processor may be further configured to perform safety diagnosis for the target battery cell by comparing a PEIS pattern with the fault PEIS pattern. The PEIS pattern is generated based on a BMS voltage and current signal corresponding to the target battery cell.

### BRIEF DESCRIPTION OF THE DRAWINGS

The above and other objects, features and advantages of the present disclosure should be more apparent from the following detailed description taken in conjunction with the accompanying drawings:

FIG. 1 is a block diagram illustrating a configuration of an electric vehicle battery diagnosing system, according to an embodiment of the present disclosure;

FIG. 2 is a flowchart illustrating an overall battery pack safety diagnosis procedure, according to an embodiment of the present disclosure;

FIG. 3 is a block diagram illustrating a detailed configuration of a battery pack safety diagnosis device, according to an embodiment of the present disclosure;

FIG. 4 is a block diagram illustrating a detailed configuration of a fault pattern generation device, according to an embodiment of the present disclosure;

FIG. 5 is a flowchart illustrating a method of a fault pattern generation device, according to an embodiment of the present disclosure;

FIG. 6 is a diagram illustrating a type of a battery electrical equivalent circuit model parameter, according to an embodiment of the present disclosure;

FIG. 7 is a diagram illustrating transfer learning application logic for generating a target cell fault PEIS pattern, according to an embodiment of the present disclosure;

FIG. 8 is a flowchart illustrating a pre-learning model design procedure, according to an embodiment of the present disclosure;

FIG. 9 is a flowchart illustrating a procedure for generating voltage data of a target battery fault cell based on transfer learning, according to an embodiment of the present disclosure;

FIG. 10 is a drawing illustrating a detailed procedure of a method for deriving a model parameter corresponding to the pre-owned cell of FIG. 9;

FIG. 11 is a diagram for mathematically illustrating a model parameter extraction process, according to an embodiment of the present disclosure;

FIG. 12 is a flowchart illustrating a fault PEIS pattern generation method in a fault pattern generation device, according to an embodiment of the present disclosure;

FIG. 13 is a diagram illustrating a transfer learning process and a transfer learning purpose applied according to an embodiment of the present disclosure; and

FIG. 14 is a diagram illustrating a computing device, according to an embodiment of the present disclosure.

### DETAILED DESCRIPTION

Hereinafter, some embodiments of the present disclosure are described in detail with reference to the accompanying drawings. In the following drawings, the same reference numerals are used throughout to designate the same or equivalent elements or components, even though the elements are shown in different drawings. In describing embodiments of the present disclosure, detailed descriptions associated with well-known functions or configurations are omitted when they may make subject matters of the present disclosure unnecessarily obscure.

In describing components of embodiments of the present disclosure, the terms first, second, A, B, (a), (b), and the like may be used herein. These terms are only used to distinguish one element from another element, but do not limit the corresponding elements irrespective of the nature, order, or priority of the corresponding elements. Furthermore, unless otherwise defined, all terms used herein, including technical or scientific terms, include the same meaning as commonly understood by one of ordinary skill in the technical field to which the present disclosure belongs. It should be understood that terms used herein should be interpreted as including a meaning that is consistent with their meaning in the context of the present disclosure and the relevant art and should not be interpreted in an idealized or overly formal sense unless expressly so defined herein.

When a component is described as being “connected,” “coupled,” or “joined” to another component, this may include not only a case where the component is directly connected, coupled, or joined to the other component, but also a case where the component is “connected,” “coupled,” or “joined” to the other component by still another component between the component and the other component. When a component, device, element, part, unit, module or the like of the present disclosure is described as having a purpose or performing an operation, function, or the like, the component, device, or element should be considered herein as being “configured to” meet that purpose or to perform that operation or function. For example, a “processor configured to (or set to) perform A, B, and C” may mean a dedicated processor (e.g., an embedded processor) for performing a corresponding operation or a specifically configured processor (e.g., a central processing unit (CPU) or an application processor) which performs corresponding operations by executing one or more software programs or computer-executable instructions which are stored in a memory. Each “part”, “unit”, “module”, “component”, “device”, “element”, and the like may separately embody or be included with a processor and a memory, such as a non-transitory computer readable media, as part of the apparatus.

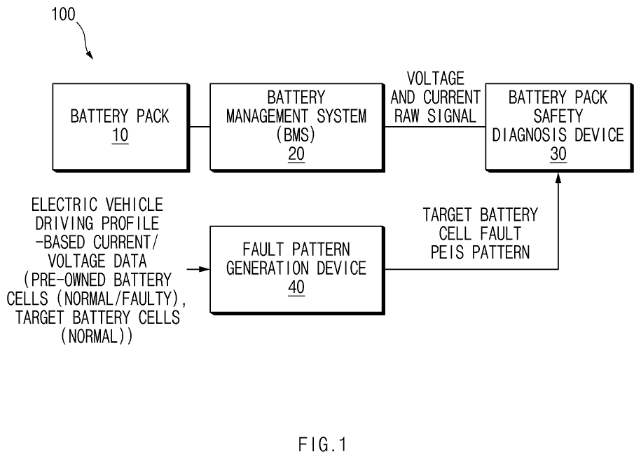

Hereinafter, various embodiments of the present disclosure are described in detail with reference to FIGS. 1-14.

FIG. 1 is a block diagram illustrating a configuration of an electric vehicle battery diagnosis system, according to an embodiment of the present disclosure.

Referring to FIG. 1, an electric vehicle battery diagnosis system 100 may include a battery pack 10, a battery management system (BMS) 20, a battery pack safety diagnosis device 30, and a fault pattern generation device 40.

To perform battery pack safety diagnosis based on Passive Electrochemical Impedance Spectroscopy (PEIS) according to an embodiment of the present disclosure, a PEIS pattern for a faulty battery is required.

When the PEIS pattern is extracted, an aperiodic voltage/current is required, but there are limitations in securing the aperiodic voltage/current due to the absence of a faulty battery.

Because constant current/constant voltage data when a simple fault occurs in the target battery is not aperiodic, the PEIS pattern is impossible to be extracted.

Accordingly, it is necessary to collect aperiodic current/voltage data in a fault state where the internal electrochemical state of the battery is not normal.

Furthermore, there are safety issues and limitations in verification of actual fault situations by artificially inducing a faulty battery. In particular, a target cell according to an embodiment of the present disclosure is in a pouch shape, not a conventional cylindrical shape, and thus there is a high possibility that positive and negative electrodes will come into direct contact when various fault situations such as overcharge/over discharge are simulated, which may lead to a fire and may prevent meaningful data on the faulty battery from being obtained. Also, there are verification limitations regarding whether the corresponding data is capable of representing the fault even when it simulates an actual fault.

To solve the above-described issues, the present disclosure may provide a battery pack safety diagnosis technology configured to precisely perform battery safety diagnosis by generating (i.e., simulating) a fault PEIS pattern corresponding to a target battery cell through transfer learning using a model obtained through pre-learning based on a driving profile of a pre-owned battery cell.

In various embodiments of the present disclosure, a faulty battery may refer to a pre-owned battery in which there is an issue in an electrochemical state, but a voltage is capable of being measured. Here, the pre-owned battery may include existing battery(conventional cylindrical batteries in normal and faulty states), and target battery(a pouch-type battery in a normal state).

The battery pack 10 is in the final form of a battery mounted on an electric vehicle. The battery pack 10 is a bundle of several modules. Each module may include several battery cells.

The module is a battery assembly in which the specific number of battery cells are bundled together and placed in a frame to protect them from external shock, heat, vibration, or the like.

The battery cell may be the basic unit of a battery capable of using electrical energy for charging/discharging and may be implemented by placing anode/cathode/separator/electrolyte in an aluminum case.

The BMS 20 may manage a temperature, a voltage, a current, or the like of the battery module.

The BMS 20 according to an embodiment may be mounted inside the battery pack 10. Various control and protection systems, such as a cooling device, may be provided inside the battery pack 10.

The BMS 20 according to an embodiment may detect a voltage difference between battery cells and may also perform cell balancing when a voltage imbalance between cells is detected.

In general, when battery stability is not secured, the risk of fire may increase. Accordingly, accurate safety diagnosis of the battery pack is important not only to ensure the performance and durability of a battery, but also to ensure a driver's safety.

The BMS 20 may monitor the voltage and current of individual cells in the battery pack 10 while a vehicle is driving. The BMS 20 may generate voltage and current signals. The BMS 20 may transmit the voltage and current signals to the battery pack safety diagnosis device 30.

The battery pack safety diagnosis device 30 may derive AC impedance data for each battery cell by performing signal processing on the voltage and current signals received from the BMS 20. Here, the voltage and current signals received from the BMS 20 are DC signals. The signal processing may include at least one of DWT or STFT.

The battery pack safety diagnosis device 30 may derive a PEIS pattern corresponding to the corresponding battery cell based on the derived AC impedance data.

The PEIS according to an embodiment of the present disclosure may extract cell-level EIS data by processing the voltage/current raw signals from the BMS 20 of a vehicle without a separate EIS device.

The DWT is a transform for decomposing a given signal into several sets, where each set is a time series of coefficients for describing time changes in a signal in the corresponding frequency band. The DWT is a mathematical process of quantifying how much energy is included within a specific frequency band at a specific time within a signal.

The actual voltage and current raw signals input from the BMS 20 include noise components (in particular, noise components in a high-frequency domain) depending on operating environments and sensor characteristics (or performance). These noise components need to be removed to extract reliable AC impedance data.

Accordingly, the DWT may be implemented to extract time domain signals by decomposing frequency level-specific signals by applying band filters for removing noise included in the voltage and current raw signals received from the BMS 20, and multi-resolution analysis (MRA) techniques for decomposing input signals into high-frequency signals and low-frequency signals.

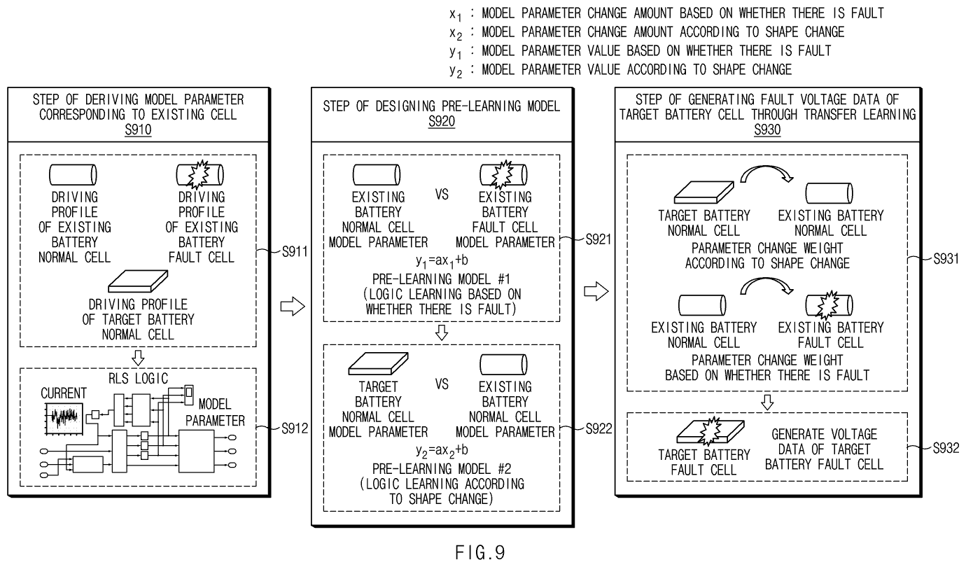

The STFT may be one of Fourier transforms of converting a time domain signal into a frequency domain signal. The STFT may be used to determine the sinusoidal frequency and phase components of a local section of a signal when the signal is changed as time elapses. In particular, as shown in FIG. 9, the STFT may be implemented as logic that divides a long time domain raw signal into short segments of the same length, performs a Fourier transform on each short segment individually, and applies Ohm's law of voltage/current in the transformed frequency domain to extract frequency-specific AC impedance.

In the case of the raw voltage and current signals input from the BMS 20 when an electric vehicle is driving, it is difficult to extract frequency-specific periodicity of a long time interval in real time. The battery pack safety diagnosis device 30, according to an embodiment of the present disclosure, may derive real-time voltage and current frequency characteristics by splitting a raw signal into segments of a short time unit through application of the STFT and then performing a Fourier transform on each segment. In an example, the battery pack safety diagnosis device 30 may apply segmenting to a continuous time domain signal. When an overlap interval between segments is set, frequency-specific AC impedance data may be extracted quickly (e.g., in units of one second), thereby diagnosing real-time safety of a battery pack.

The battery pack safety diagnosis device 30 may generate a PEIS pattern by extracting PEIS data for individual cells within a module through the signal processing described above. Here, the PEIS pattern may be derived for each SOC environment.

The battery pack safety diagnosis device 30 may diagnose whether a battery cell fails by comparing the generated PEIS pattern with the PEIS fault pattern obtained through pre-learning.

The battery pack safety diagnosis device 30, according to an embodiment, may be mounted inside the battery pack 10. According to another embodiment, the battery pack safety diagnosis device 30 may be implemented as an integrated device with the BMS 20.

The fault pattern generation device 40 may estimate a fault PEIS pattern for a target cell through learning based on current/voltage data based on an electric vehicle driving profile obtained through the electric vehicle driving.

The fault pattern generation device 40 may provide information about the estimated fault PEIS pattern to the battery pack safety diagnosis device 30.

The fault pattern generation device 40 may be implemented to estimate a fault PEIS pattern for a cell of a new pouch-type battery (i.e., a target battery), of which the shape is different from that of a conventional cylindrical battery.

The fault pattern generation device 40 according to an embodiment may generate a pre-learning model by performing relationship learning based on driving profile data for a pre-owned battery. The fault pattern generation device 40 may estimate the fault PEIS pattern for the target cell by performing transfer learning based on the pre-learning model.

The fault pattern generation device 40 according to an embodiment may extract a target cell fault model parameter by applying the weight of the pre-learning model to the transfer learning model and may estimate a fault terminal voltage corresponding to the corresponding target battery cell by designing an electrical equivalent circuit model based on the extracted fault model parameter. The fault pattern generation device 40 may extract AC impedance data by performing signal processing based on the estimated fault terminal voltage and may derive a fault PEIS pattern corresponding to the target battery cell based on the extracted AC impedance data.

In an embodiment of FIG. 1, the battery pack safety diagnosis device 30 and the fault pattern generation device 40 are illustrated as separate devices. In another embodiment, the battery pack safety diagnosis device 30 and the fault pattern generation device 40 may be implemented as one device.

At least one of the battery pack safety diagnosis device 30 or the fault pattern generation device 40, according to an embodiment of the present disclosure, may be implemented as part of the BMS 20.

In an embodiment, the BMS 20 may be implemented inside the battery pack 10.

The target cell fault PEIS pattern generation procedure of the fault pattern generation device 40 is further described through the descriptions of drawings below.

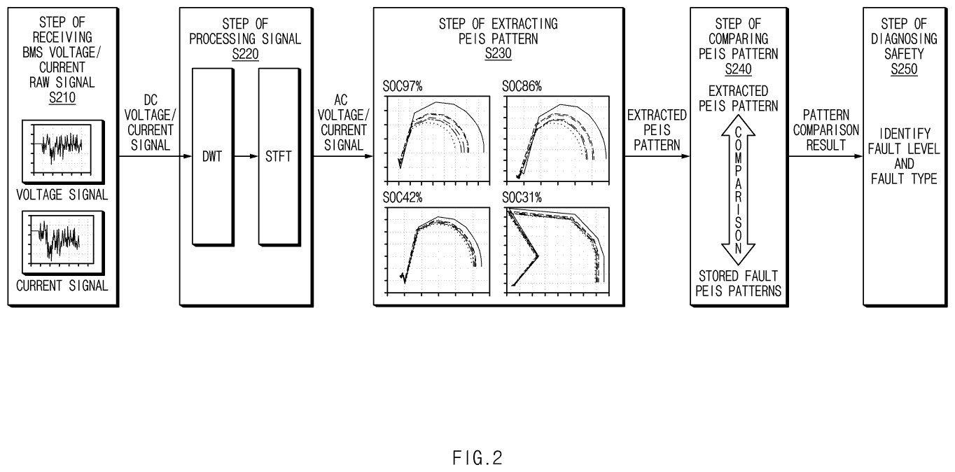

FIG. 2 is a flowchart illustrating an overall battery pack safety diagnosis procedure, according to an embodiment of the present disclosure.

Referring to FIG. 2, the battery pack safety diagnosis procedure may include step S210 of receiving a BMS voltage/current raw signal, step S220 of processing a signal, S230 of extracting a PEIS pattern, step S240 of comparing a PEIS pattern, and step S250 of diagnosing safety.

In step S210 of receiving a BMS voltage/current raw signal, the battery pack safety diagnosis device 30 may receive voltage and current raw signals from the BMS 20. Here, the voltage and current raw signals may be DC signals.

In step S220 of processing a signal, the battery pack safety diagnosis device 30 may remove a noise component included in the received voltage and current raw signals, and then may perform DWT for extracting a time domain signal by decomposing frequency level-specific data.

Moreover, in step S220 of processing a signal, the battery pack safety diagnosis device 30 may perform STFT for extracting frequency-specific AC impedance data based on DC voltage and current signal data of individual cells in the battery pack 10 by converting a time domain signal into a frequency domain signal.

In step S230 of extracting a PEIS pattern, the battery pack safety diagnosis device 30 may derive a PEIS pattern based on AC impedance data.

In step S240 of comparing a PEIS pattern, the battery pack safety diagnosis device 30 may compare the derived PEIS pattern with a fault PEIS pattern estimated through transfer learning.

In step S250 of diagnosing safety, the battery pack safety diagnosis device 30 may perform real-time safety diagnosis on the corresponding battery cell based on the pattern comparison results.

The present disclosure may perform precise safety diagnosis on a target battery (pouch-type battery) by obtaining fault data for a target cell (pouch-type battery normal cell), which is not possessed, through transfer learning based on pre-owned driving profile data.

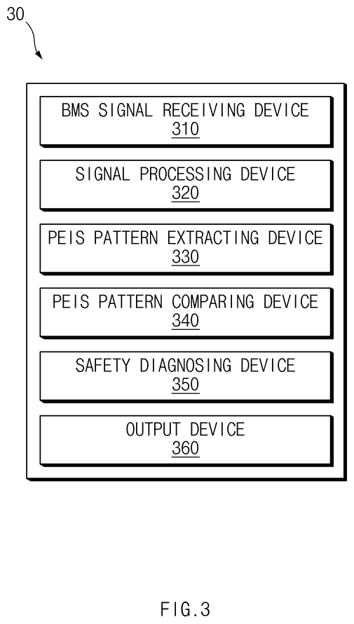

FIG. 3 is a block diagram illustrating a detailed configuration of a battery pack safety diagnosis device, according to an embodiment of the present disclosure.

Referring to FIG. 3, the battery pack safety diagnosis device 30 may be configured to include at least one of a BMS signal receiving device 310, a signal processing device 320, a PEIS pattern extracting device 330, a PEIS pattern comparing device 340, a safety diagnosing device 350, or an output device 360.

The BMS signal receiving device 310 may receive voltage and current raw signals from the BMS 20. Here, the voltage and current raw signals may be DC signals.

The signal processing device 320 may remove noise components included in the received voltage and current raw signals. The signal processing device 320 may then perform DWT for extracting time domain signals by decomposing frequency level-specific data and STFT for extracting frequency-specific AC impedance data based on DC voltage and current signals of individual cells in the battery pack 10 by converting time domain signals into frequency domain signals.

The PEIS pattern extracting device 330 may extract real-time PEIS patterns based on the AC impedance data.

The PEIS pattern comparing device 340 may compare the extracted PEIS pattern with a fault PEIS pattern estimated through transfer learning.

The safety diagnosing device 350 may diagnose whether a battery cell fails based on the PEIS pattern comparison results.

When a result of the battery pack safety diagnosis indicates that a specific fault event is detected, the output device 360 may generate a warning alarm message corresponding to the corresponding event and may transmit the warning alarm message to an output device (e.g., a cluster displayed driving information of vehicle) equipped in a vehicle.

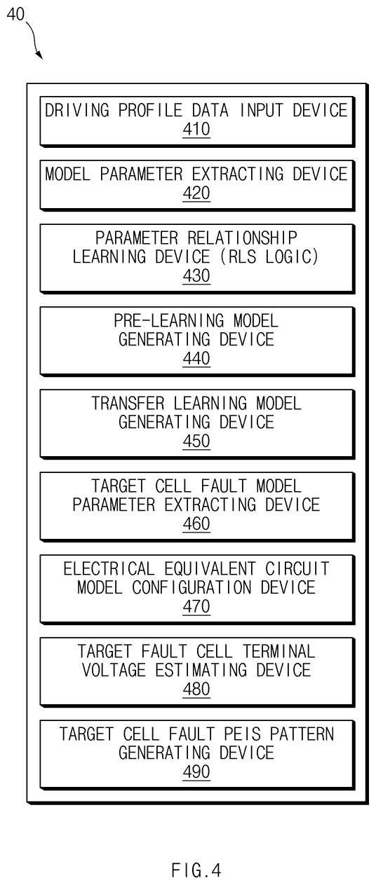

FIG. 4 is a block diagram illustrating a detailed configuration of a fault pattern generation device, according to an embodiment of the present disclosure.

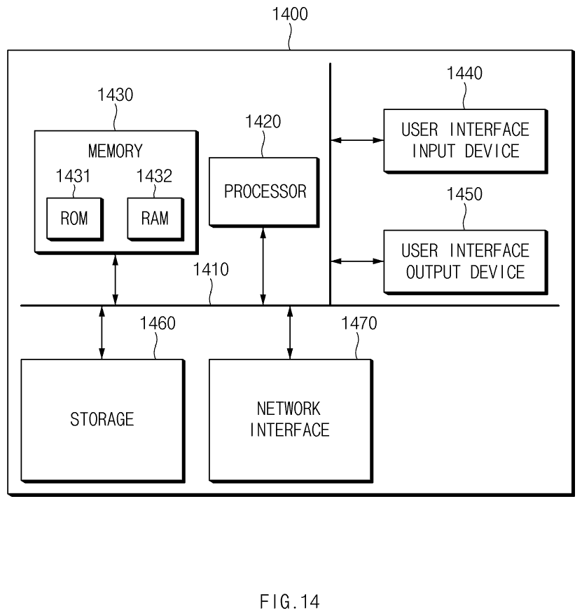

Referring to FIG. 4, the fault pattern generation device 40 may be configured to include a driving profile data input device 410, a model parameter extracting device 420, a parameter relationship learning device 430, a pre-learning model generating device 440, a transfer learning model generating device 450, a target cell fault model parameter extracting device 460, an electrical equivalent circuit model configuration device 470, a target fault cell terminal voltage estimating device 480, and a target cell fault PEIS pattern generating device 490. The driving profile data input device 410, the model parameter extracting device 420, the parameter relationship learning device 430, the pre-learning model generating device 440, the transfer learning model generating device 450, the target cell fault model parameter extracting device 460, the electrical equivalent circuit model configuration device 470, the target fault cell terminal voltage estimating device 480, and the target cell fault PEIS pattern generating device 490 may be implemented by one or more processors such as the processor 1420 shown in FIG. 14.

The driving profile data input device 410 may receive driving profile data for a pre-owned battery. Here, the pre-owned battery may include a normal cylindrical battery, a faulty cylindrical battery, and a normal target (pouch-type) battery, and the driving profile data may include voltage and current data corresponding to each pre-owned battery.

The model parameter extracting device 420 may extract a model parameter corresponding to each battery cell by applying cell-specific driving profile data of a pre-owned battery to RLS logic.

The parameter relationship learning device 430 may perform relationship learning based on the extracted model parameters for each battery cell. Here, the relationship learning may include relationship learning between existing (cylindrical) battery normal cells and existing (cylindrical) battery fault cells and relationship learning between existing (cylindrical) battery normal cells and target (pouching-type) battery normal cells.

The pre-learning model generating device 440 may generate first and second pre-learning models based on the relationship learning results. Here, the first learning model is generated based on the relationship learning results between the existing (cylindrical) battery normal cells and the existing (cylindrical) battery fault cells. The first learning model refers to a learning model for monitoring model parameter changes based on whether there is a fault. The second learning model is generated based on the relationship learning results between the existing (cylindrical) battery normal cells and the target (pouching) battery normal cells. The second learning model refers to a learning model for monitoring model parameter changes according to a change in the shape of a battery cell.

The transfer learning model generating device 450 may generate a new network (i.e., a transfer learning model) by applying a weight (i.e., a pre-learning model weight) derived through the relationship learning to the transfer learning model. Specifically, information (i.e., information about the input/output relationship of the new network) related to the fault of the target battery cell is absent, and thus the weight of the pre-trained network (i.e., the pre-learning model) is applied to the new network.

The target cell fault model parameter extracting device 460 may extract a fault model parameter corresponding to a target battery cell based on the generated transfer learning model.

The electrical equivalent circuit model configuration device 470 may automatically design an electrical equivalent circuit model based on the fault model parameter corresponding to the target battery cell.

The target fault cell terminal voltage estimating device 480 may estimate a terminal voltage at a point in time, at which the target battery cell fails, based on the designed electrical equivalent circuit model.

The target cell fault PEIS pattern generating device 490 may generate a target cell fault PEIS pattern through signal processing based on the terminal voltage of the estimated target battery fault cell.

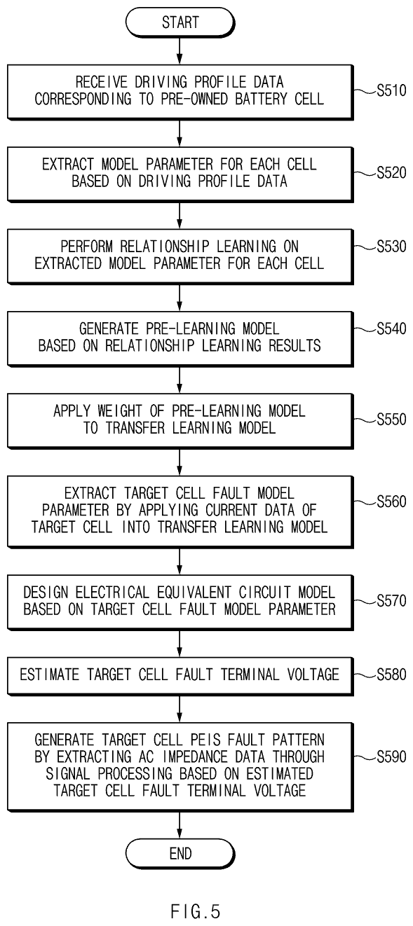

FIG. 5 is a flowchart illustrating a method executed by a fault pattern generation device 40, according to an embodiment of the present disclosure.

Referring to FIG. 5, the fault pattern generation device 40 may receive driving profile data corresponding to a pre-owned battery cell (S510).

The fault pattern generation device 40 may extract a model parameter for each cell based on the received driving profile data (S520).

The fault pattern generation device 40 may perform relationship learning on the extracted model parameter for each cell (S530).

The fault pattern generation device 40 may generate a pre-learning model based on the relationship learning results (S540).

The fault pattern generation device 40 may apply a weight of the pre-learning model to a transfer learning model (S550).

The fault pattern generation device 40 may extract a target cell fault model parameter by inputting current data of the target cell into the transfer learning model (S560).

The fault pattern generation device 40 may design an electrical equivalent circuit model based on the target cell fault model parameter (S570).

The fault pattern generation device 40 may estimate a target cell fault terminal voltage by using the electrical equivalent circuit model (S580).

The fault pattern generation device 40 may generate a target cell PEIS fault pattern by extracting AC impedance data through signal processing based on the estimated target cell fault terminal voltage (S590).

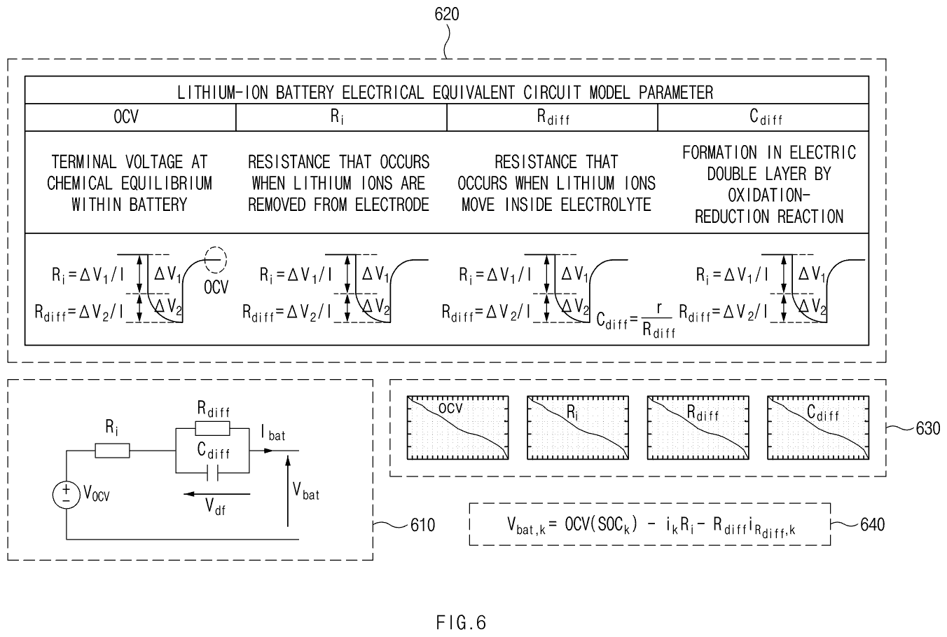

FIG. 6 is a diagram illustrating a type of a battery electrical equivalent circuit model parameter, according to an embodiment of the present disclosure.

Referring to reference numerals 610 and 620 of FIG. 6, components of an electrical equivalent circuit model simulating a battery voltage may be composed of resistance Rᵢ that occurs when lithium ions are removed from an electrode, resistance R_{diff} that occurs when lithium ions move inside electrolyte, and charge amount C_{diff} formed in an electric double layer by the oxidation-reduction reaction.

A battery model parameter may be obtained by conducting an open circuit voltage (OCV) measurement experiment for each battery SOC. For example, when the voltage of the OCV is measured, the unit of battery discharge capacity may be defined by a user. For example, the discharge capacity unit may be set to 1%, 5%, or 10%, but is not limited thereto.

Reference numeral 630 shows changes in battery model parameters when the battery capacity is discharged in a certain unit.

When the battery model parameters are derived, a battery terminal voltage V_{bat} may be estimated, as shown in reference numeral 640.

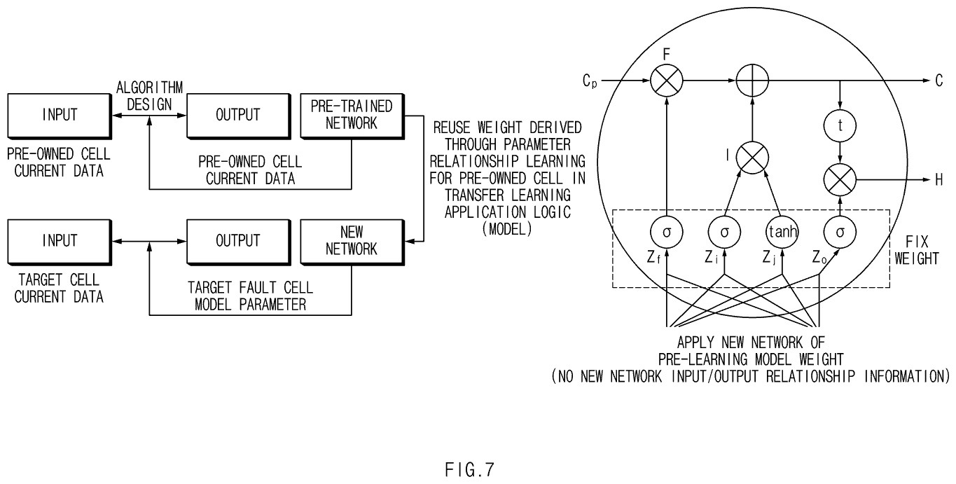

FIG. 7 is a diagram illustrating transfer learning application logic for generating a target cell fault PEIS pattern, according to an embodiment of the present disclosure.

Transfer learning is a machine learning technique that finely tunes a pre-trained model for one task so as to fit a new relevant task.

Training a machine learning model requires a lot of time to accumulate knowledge and to identify patterns. Moreover, it also requires large data sets and requires a lot of computational costs. In the transfer learning, the pre-trained model retains basic knowledge about tasks, features, weights, and functions, and thus it may adapt to new tasks more quickly. In other words, better results on new jobs may be obtained while much smaller data sets and fewer resources are used.

Referring to FIG. 7, the transfer learning application logic according to an embodiment of the present disclosure may derive a weight by performing relationship learning between pre-learning models generated based on input/output data corresponding to pre-owned battery cells, and may apply the weight of a new network that performs transfer learning based on the pre-learning model weight, thereby solving problems (e.g., problems of lack of information on target fault cells)of lack of input/output relationship information through the new network. To this end, the transfer learning application logic may train a parameter estimation model and may train parameter change logic.

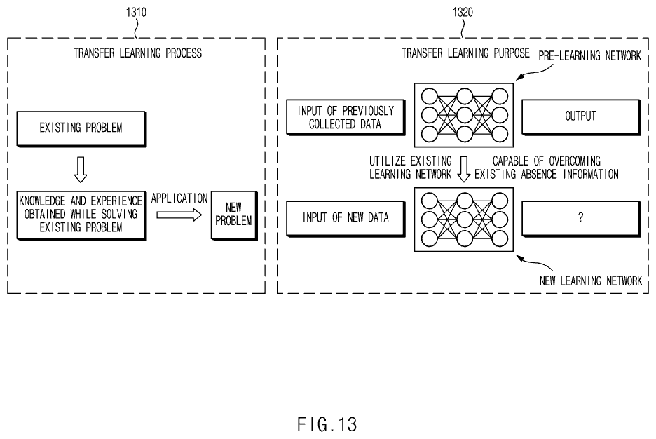

In general, as illustrated in reference numeral 1310 of FIG. 13, the transfer learning means applying knowledge and experience, which are obtained while solving existing problems, to new problems. In particular, as shown in reference numeral 1320, the transfer learning may be used to construct a new learning network for overcoming existing missing information based on a pre-learning network created through learning based on previously collected data. Newly generated data may be input into the new learning network to obtain the existing missing information.

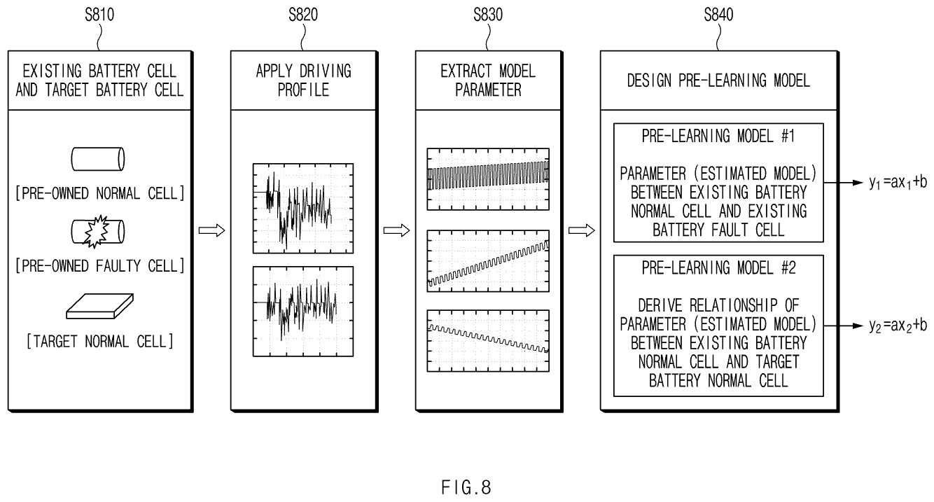

FIG. 8 is a flowchart illustrating a pre-learning model design procedure, according to an embodiment of the present disclosure.

Referring to FIG. 8, the fault pattern generation device 40 may obtain a driving profile corresponding to an existing battery cell and a target battery cell (S810). Here, the existing battery cell may include normal cells and faulty cells, and the target battery cell may include only normal cells. In other words, information about the target fault cell may be absent.

The fault pattern generation device 40 may apply a driving profile (S820) and extract model parameters corresponding to an existing battery cell (normal/faulty) and a target battery cell (normal) based on the applied driving profile (S830).

The fault pattern generation device 40 may generate a parameter relationship expression (i.e., a pre-learning model) by performing relationship learning between the extracted model parameters for each battery cell (S840). In an embodiment, the fault pattern generation device 40 may generate a first pre-learning model, which is a parameter relationship (e.g., y₁=ax₁+b) as shown in FIG. 9, by training parameter change logic according to the occurrence of a fault between an existing battery normal cell and an existing battery fault cell. Moreover, the fault pattern generation device 40 may generate a second pre-learning model, which is a parameter relationship (e.g., y₂=ax₂+b) as shown in FIG. 9, by training parameter change logic according to a battery shape change between the existing battery normal cell and the target battery normal cell. Here, x₁ and y₁ denote a model parameter change amount based on whether there is a fault, and a model parameter value based on whether there is a fault, respectively. x₂ and y₂ denote a model parameter change amount according to a shape change, and a model parameter value according to a shape change, respectively.

FIG. 9 is a flowchart illustrating a procedure for generating voltage data of a target battery fault cell based on transfer learning, according to an embodiment of the present disclosure.

Referring to FIG. 9, a procedure for generating voltage data of a target battery fault cell based on transfer learning may largely include step S910 of deriving a model parameter corresponding to a pre-owned cell, step S920 of designing a pre-learning model, and step S930 of generating voltage data of a target battery fault cell through transfer learning.

In step S910 of deriving a model parameter corresponding to a pre-owned battery cell, the fault pattern generation device 40 may obtain a driving profile corresponding to an existing battery cell in a normal state, a driving profile corresponding to an existing battery cell in a faulty state, and a driving profile corresponding to a target battery cell in a normal state (S911). The fault pattern generation device 40 may extract a model parameter corresponding to each cell by applying the driving profile for existing battery cells to RLS logic (S912).

In step S920 of designing a pre-learning model, the fault pattern generation device 40 may generate a parameter relationship expression (i.e., a pre-learning model) by performing relationship learning between the extracted model parameters for each battery cell.

In detail, the fault pattern generation device 40 may generate a first pre-learning model, which is a parameter relationship (e.g., y₁=ax₁+b), by training parameter change logic according to the occurrence of a fault between an existing battery normal cell and an existing battery fault cell (S921). Moreover, the fault pattern generation device 40 may generate a second pre-learning model, which is a parameter relationship (e.g., y₂=ax₂+b), by training parameter change logic according to a battery shape change between the existing battery normal cell and the target battery normal cell (S922). Here, x₁ and y₁ denote a model parameter change amount based on whether there is a fault, and a model parameter value based on whether there is a fault, respectively. x₂ and y₂ denote a model parameter change amount according to a shape change, and a model parameter value according to a shape change, respectively.

In step S930 of generating voltage data of a target battery fault cell through transfer learning, the fault pattern generation device 40 may apply the weight of each pre-learning model to a new learning model (S931) and may generate voltage data corresponding to a target battery fault cell by using a new learning model to which the weight is applied (S932). Here, the weight for each pre-learning model may include a parameter change weight according to a shape change and a parameter change weight based on whether there is a fault.

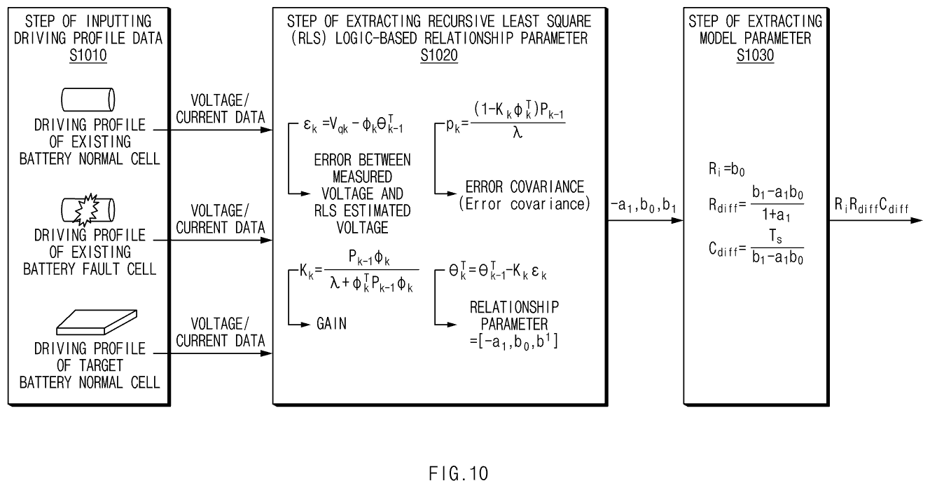

FIG. 10 is a drawing illustrating a detailed procedure of a step of deriving a model parameter corresponding to a pre-owned battery cell of FIG. 9.

Referring to FIG. 10, a step of deriving a model parameter corresponding to a pre-owned cell may include step S1010 of inputting driving profile data, step S1020 of extracting a RLS logic-based relationship parameter, and step S1030 of extracting a model parameter.

In step S1010 of inputting driving profile data, the fault pattern generation device 40 may input driving profile data corresponding to each of pre-owned battery cells into RLS logic (S1010). Here, the pre-owned battery cells may be composed of an existing battery normal cell, an existing battery fault cell, and a target battery normal cell.

The fault pattern generation device 40 may extract relationship parameters by entering driving profile data for each pre-owned cell into the RLS logic and then perform model parameter change logic learning for each cell (S1020).

The fault pattern generation device 40 may extract cell-specific model parameters based on the extracted cell-specific relationship parameters (S1030).

Afterwards, the fault pattern generation device 40 may generate first and second pre-learning models by performing logic learning according to shape changes and logic learning based on whether there is a fault, based on the extracted model parameters for each cell.

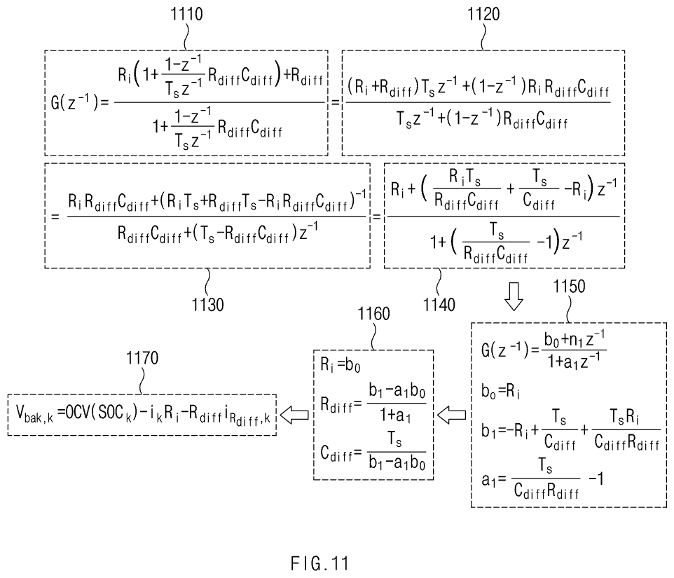

FIG. 11 is a diagram for mathematically describing a model parameter extraction process, according to an embodiment of the present disclosure.

Referring to FIG. 11, as illustrated in reference numeral 1110, G(z⁻¹), which is a transfer function of battery impedance in s-domain, may be derived. A mathematical expression of reference numeral 1120 may be obtained by multiplying Tₛz⁻¹ (function for inverse Z transform) by the numerator and denominator of the transfer function G(z⁻¹), and a mathematical expression of reference numeral 1130 may be obtained by organizing the mathematical expression of reference numeral 1120 by degree. A mathematical expression of reference numeral 1140 may be obtained by dividing the denominator and numerator of the mathematical expression of reference numeral 1130 by R_{diff}C_{diff}.

Afterwards, relationship parameters a₁, b₀, and b₁ may be obtained from the mathematical expression of reference numeral 1150. As shown in reference numeral 1160, model parameters Rᵢ, R_{diff}, and C_{diff} may be derived based on the relationship parameters. Finally, as shown in reference numeral 1170, a terminal voltage V_{bat}, k of the k-th battery cell may be obtained based on the derived model parameters and an OCV value according to the corresponding SOC.

As described above, the fault pattern generation device 40 according to an embodiment of the present disclosure may calculate the model parameter value of the corresponding battery cell by deriving the transfer function of battery impedance in s-domain, applying inverse z-transform for discretization, and performing forward Euler/Bilinear transformation.

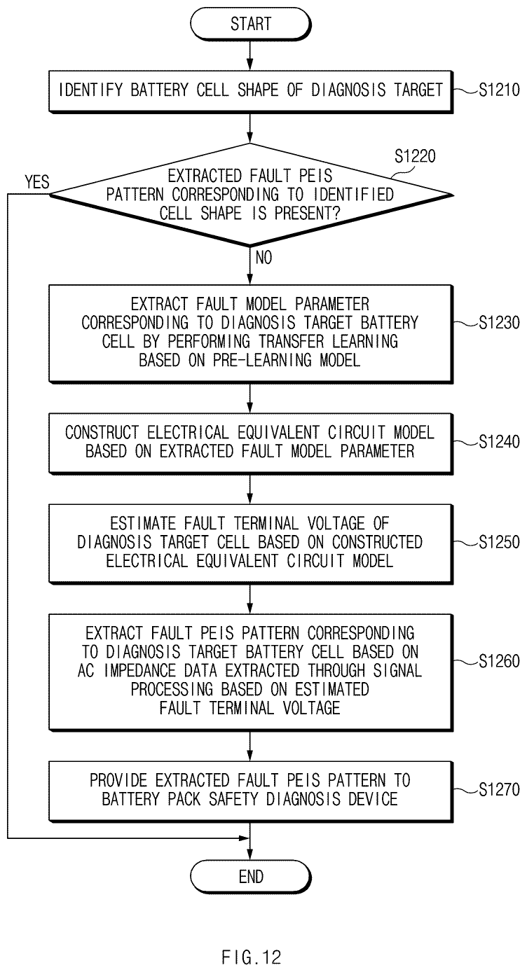

FIG. 12 is a flowchart illustrating a fault PEIS pattern generation method executed by a fault pattern generation device 40, according to an embodiment of the present disclosure.

Referring to FIG. 12, the fault pattern generation device 40 may identify a battery cell shape of a diagnosis target (i.e., a target) (S1210) and may determine whether the extracted fault PEIS pattern corresponding to the identified cell shape is present (S1220).

When the identification result indicates that there is no fault PEIS pattern corresponding to the identified cell shape (NO in S1220), the fault pattern generation device 40 may extract a fault model parameter corresponding to a diagnosis target battery cell by performing transfer learning based on a pre-learning model (S1230).

The fault pattern generation device 40 may estimate the fault terminal voltage of the diagnosis target cell (S1250) by constructing an electrical equivalent circuit model based on the extracted fault model parameter (S1240).

The fault pattern generation device 40 may extract AC impedance data through signal processing based on the estimated fault terminal voltage and then may extract a fault PEIS pattern corresponding to a diagnosis target battery cell by using the AC impedance data (S1260).

The fault pattern generation device 40 may provide information about the fault PEIS pattern corresponding to the diagnosis target battery cell to the battery pack safety diagnosis device 30 (S1270).

FIG. 14 illustrates a computing device, according to an embodiment of the present disclosure.

Referring to FIG. 14, a computing device 1400 may include at least one of at least one processor 1420, a memory 1430, a user interface input device 1440, a user interface output device 1450, storage 1460, or a network interface 1470, which is connected via a bus 1410.

The network interface 1470 according to an embodiment may perform at least one of diagnostic communication, intra-vehicle communication, or communication with a server outside a vehicle. The network interface 1470 may operate in conjunction with the BMS 20, a navigation system (e.g., an AVN (Audio, Video and Navigation) system), or a cluster through the in-vehicle communication. The in-vehicle communication according to an embodiment may include, but is not limited to, at least one of Controller Area Network (CAN) communication, Local Interconnect Network (LIN) communication, FlexRay communication, MOST (Media Oriented Systems. Transport) communication, or Ethernet communication.

The processor 1420 may be a central processing unit (CPU) or a semiconductor device that processes instructions stored in the memory 1430 and/or the storage 1460. Each of the memory 1430 and the storage 1460 may include various types of volatile or nonvolatile storage media. For example, the memory 1430 may include a read only memory (ROM) 1431 and a random access memory (RAM) 1432.

Thus, the operations of the methods or algorithms described in connection with the embodiments disclosed in the specification may be directly implemented with a hardware module, a software module, or a combination of the hardware module and the software module, which is executed by the processor 1420. The software module may reside on a storage medium (i.e., the memory 1430 and/or the storage 1460) such as a RAM, a flash memory, a ROM, an erasable and programmable ROM (EPROM), an electrically EPROM (EEPROM), a register, a hard disc, a removable disc, or a compact disc-ROM (CD-ROM).

The storage medium may be coupled to the processor 1420. The processor 1420 may read out or retrieve information from the storage medium and may write information in the storage medium. Alternatively, the storage medium may be integrated with the processor 1420. The processor 1420 and the storage medium may be implemented with an application specific integrated circuit (ASIC). The ASIC may be provided within a controller in the vehicle. Alternatively, the processor 1420 and the storage medium may reside as separate components within an electric vehicle.

In an embodiment, the computing device 1400 may be implemented to perform the above-described at least one function and the above-described at least one method disclosed in FIGS. 1-13 described above and may be applied to at least one of the above-described components of the electric vehicle battery diagnosis system 100.

The above description is merely an example of the technical idea of the present disclosure. Various modifications and variations may be made by one of ordinary skill in the art without departing from the essential characteristic of the present disclosure.

Accordingly, embodiments of the present disclosure are intended not to limit but to explain the technical idea of the present disclosure. The scope and spirit of the present disclosure is not limited by the above embodiments. The scope of protection of the present disclosure should be construed by the attached claims. All equivalents thereof should be construed as being included within the scope of the present disclosure.

The present technology may provide a method and an apparatus for generating a PEIS fault pattern that is used for electric vehicle battery pack safety diagnosis.

Moreover, the present technology may provide an electric vehicle battery pack safety diagnosis technology that may secure high-precision battery pack safety diagnosis performance by generating a PEIS fault pattern capable of simulating the electrochemical characteristics of a battery through signal processing of BMS input voltage and current raw signals.

Furthermore, the present technology may simulate a voltage behavior for each battery fault type, which is difficult to be obtained, by applying pre-owned faulty battery data-based model parameter estimation and transfer learning methods, thereby securing PEIS fault pattern generation-based high-precision safety diagnosis performance.

Also, the present technology may simulate a voltage behavior suitable for the desired shape and type of a target battery by using the pre-owned battery with an unstable internal electrochemical state, thereby overcoming limitations in conventional battery safety verification as well as saving time and costs.

In addition, the present technology may utilize voltage data of a battery, which is obtained by simulating the obtained fault situation as an answer sheet for safety diagnosis, thereby improving the reliability and robustness of a BMS safety diagnosis algorithm.

A variety of effects directly or indirectly understood through the present disclosure are provided by the present disclosure.

Hereinabove, although the present disclosure was described with reference to various embodiments and the accompanying drawings, the present disclosure is not limited thereto but may be variously modified and altered by those of ordinary skill in the art to which the present disclosure pertains without departing from the spirit and scope of the present disclosure claimed in the following claims.

What is claimed is:

1. A fault pattern generating method for electric vehicle battery safety diagnosis, the method comprising:
generating a pre-learning model based on a driving profile corresponding to a pre-owned battery cell;
generating a new learning model for transfer learning based on the pre-learning model; and
generating a fault passive electrochemical impedance spectroscopy (PEIS) pattern corresponding to a target battery cell by inputting current data corresponding to the target battery cell into the new learning model,
wherein the pre-owned battery cell includes an existing battery cell in a normal state, an existing battery cell in a faulty state, and the target battery cell in a normal state.

2. The method of claim 1, wherein generating the pre-learning model includes:
applying the driving profile to recursive least square (RLS) logic;
extracting a model parameter for a respective pre-owned battery cell; and
generating the pre-learning model by performing relationship learning on the extracted model parameter for the respective pre-owned battery cell.

3. The method of claim 2, wherein the pre-learning model includes:
a first pre-learning model generated by training parameter change logic based on occurrence of a fault between the existing battery cell in the normal state and the existing battery cell in the faulty state; and
a second pre-learning model generated by training parameter change logic based on a shape change between the existing battery cell in the normal state and the target battery cell in the normal state.

4. The method of claim 3, wherein a weight derived through relationship learning between the first pre-learning model and the second pre-learning model is applied to the new learning model.

5. The method of claim 2, wherein the model parameter includes:
Rᵢ, wherein Rᵢ is resistance occurring based on a lithium ion being removed from an electrode in an electrical equivalent circuit model for simulating a corresponding battery cell voltage;
R_{diff}, wherein R_{diff} is resistance occurring based on the lithium ion moving inside electrolyte; and
C_{diff}, wherein C_{diff} is a charge amount of an electric double layer formed by oxidation-reduction reaction.

6. The method of claim 2, wherein the model parameter is extracted for each battery State-of-Charge (SOC).

7. The method of claim 1, wherein generating the fault PEIS pattern corresponding to the target battery cell includes:
extracting a fault model parameter corresponding to the target battery cell;
constructing an electrical equivalent circuit model based on the extracted fault model parameter;
estimating a fault terminal voltage of the target battery cell based on the electrical equivalent circuit model; and
generating the fault PEIS pattern based on AC impedance data extracted through signal processing based on the fault terminal voltage.

8. The method of claim 7, wherein the fault terminal voltage is estimated based on an open circuit voltage based on a battery charge state of the target battery cell and the extracted fault model parameter.

9. The method of claim 7, wherein the signal processing includes at least one of Discrete Wavelet Transform (DWT) or Short-Term Fourier Transform (STFT).

10. The method of claim 1, wherein safety diagnosis for the target battery cell is performed by comparing a PEIS pattern with the fault PEIS pattern, wherein the PEIS pattern is generated based on a Battery Management System (BMS) voltage and current signal corresponding to the target battery cell.

11. A computing device configured to generate a fault pattern for diagnosing safety of an electric vehicle battery, the computing device comprising:
a memory configured to store computer-executable instructions; and
a processor coupled with the memory, the processor configured to execute the computer-executable instructions to:
generate a pre-learning model based on a driving profile corresponding to a pre-owned battery cell;
generate a new learning model for transfer learning based on the pre-learning model; and
generate a fault PEIS pattern corresponding to a target battery cell by inputting current data corresponding to the target battery cell into the new learning model,
wherein the pre-owned battery cell includes an existing battery cell in a normal state, an existing battery cell in a faulty state, and the target battery cell in a normal state.

12. The computing device of claim 11, wherein the processor is further configured to:
extract a model parameter for a respective pre-owned battery cell by applying the driving profile to recursive least square (RLS) logic; and
generate the pre-learning model by performing relationship learning on the extracted model parameter for the respective pre-owned battery cell.

13. The computing device of claim 12, wherein the pre-learning model includes:
a first pre-learning model generated by training parameter change logic according to occurrence of a fault between the existing battery cell in the normal state and the existing battery cell in the faulty state; and
a second pre-learning model generated by training parameter change logic according to a shape change between the existing battery cell in the normal state and the target battery cell in the normal state.

14. The computing device of claim 13, wherein the processor is further configured to:
apply a weight derived through relationship learning between the first pre-learning model and the second pre-learning model to the new learning model.

15. The computing device of claim 12, wherein the model parameter includes:
Rᵢ, wherein Rᵢ is resistance occurring based on a lithium ion being removed from an electrode in an electrical equivalent circuit model for simulating a corresponding battery cell voltage;
R_{diff}, wherein R_{diff} is resistance occurring when the lithium ion moving inside electrolyte; and
C_{diff}, wherein C_{diff} is a charge amount of an electric double layer formed by oxidation-reduction reaction.

16. The computing device of claim 12, wherein the model parameter is extracted for each battery SOC.

17. The computing device of claim 11, wherein the processor is further configured to:
construct an electrical equivalent circuit model by extracting a fault model parameter corresponding to the target battery cell;
estimate a fault terminal voltage of the target battery cell based on the electrical equivalent circuit model; and
generate the fault PEIS pattern based on AC impedance data extracted through signal processing based on the estimated fault terminal voltage.

18. The computing device of claim 17, wherein the processor is further configured to:
estimate the fault terminal voltage based on an open circuit voltage based on a battery charge state of the target battery cell and the extracted fault model parameter.

19. The computing device of claim 17, wherein the signal processing includes at least one of Discrete Wavelet Transform (DWT) or Short-Term Fourier Transform (STFT).

20. The computing device of claim 11, wherein the processor is further configured to:
perform safety diagnosis for the target battery cell by comparing a PEIS pattern with the fault PEIS pattern, wherein the PEIS pattern is generated based on a BMS voltage and current signal corresponding to the target battery cell.
